(19) United States
(12) Patent Application Publication
(10) Pub. No.: US 2024/0379630 A1
(43) Pub. Date: Nov. 14, 2024

(54) ELECTRONIC DEVICE

(71) Applicant: InnoLux Corporation, Miao-Li County (TW)

(72) Inventor: Shun-Yuan HU, Miao-Li County (TW)

(73) Assignee: InnoLux Corporation, Miao-Li County (TW)

(21) Appl. No.: 18/633,559

(22) Filed: Apr. 12, 2024

Related U.S. Application Data
(60) Provisional application No. 63/465,259, filed on May 10, 2023.

(30) Foreign Application Priority Data
Jan. 25, 2024 (CN) 202410103533.6

(51) Int. Cl. H01L 25/075; H01L 33/60

(52) U.S. Cl. CPC H01L 25/0753; H01L 33/60

(57) ABSTRACT

An electronic device is provided by the present disclosure. The electronic device includes a substrate, a plurality of light emitting elements disposed on the substrate, a cover layer disposed on the substrate and covering the plurality of light emitting elements, and a dam wall unit disposed between adjacent two of the plurality of light emitting elements. The dam wall unit includes a bottom surface adjacent to a top surface of the substrate, and a spacing is included between the bottom surface of the dam wall unit and the top surface of the substrate.

### CROSS REFERENCE TO RELATED APPLICATION

This application claims the benefit of U.S. Provisional Application No. 63/465,259, filed on May 10, 2023. The content of the application is incorporated herein by reference.

### BACKGROUND OF THE DISCLOSURE

### 1. Field of the Disclosure

The present disclosure relates to an electronic device, and more particularly to an electronic device including reflective dam wall units.

### 2. Description of the Prior Art

As the requirements for current light emitting diode displays increase, the chip on board (COB) process has been developed to reduce the spacing between light emitting units, thereby improving the performance of the light emitting diode displays. The chip on board process includes bonding the light emitting diode chip to a substrate, and then providing a cover layer on the substrate to cover the light emitting diode chip to form a package structure. However, the disposition of the cover layer may cause total reflection of light and reduce the amount of output light from the light emitting diode display. Therefore, to improve the above-mentioned problems is still an important issue in the present field.

### SUMMARY OF THE DISCLOSURE

The present disclosure aims at providing an electronic device.

An electronic device is provided by the present disclosure. The electronic device includes a substrate, a plurality of light emitting elements disposed on the substrate, a cover layer disposed on the substrate and covering the plurality of light emitting elements, and a dam wall unit disposed between adjacent two of the plurality of light emitting elements. The dam wall unit includes a bottom surface adjacent to a top surface of the substrate, and a spacing is included between the bottom surface of the dam wall unit and the top surface of the substrate.

An electronic device is provided by the present disclosure. The electronic device includes a substrate, a light emitting element disposed on the substrate, a cover layer disposed on the substrate and covering the light emitting element, a dam wall unit disposed on the substrate and extending along a first direction, another dam wall unit disposed on the substrate and extending along a second direction different from the first direction, and a medium layer located on the cover layer. The light emitting element has a height H1, the dam wall unit has a height H2, the another dam wall unit has a height H3, in a top view direction of the electronic device, a minimum distance A1 is included between the dam wall unit and the light emitting element, a minimum distance B1 is included between the another dam wall unit and the light emitting element, the cover layer has a refractive index N1, the medium layer has a refractive index N2, and the minimum distance A1 and the minimum distance B1 satisfy following equations:

$${tan}^{- 1} ( A 1 / ( H 2 - H 1 ) ) \geq {sin}^{- 1} ( N 2 / N 1 ) ; and$$

$${tan}^{- 1} ( B 1 / ( H 3 - H 1 ) ) \geq {sin}^{- 1} ( N 2 / N 1 ) .$$

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates a top view of the electronic device according to the first embodiment of the present disclosure.

FIG. 3 schematically illustrates a cross-sectional view of an electronic device according to a second embodiment of the present disclosure.

FIG. 4 schematically illustrates a cross-sectional view of an electronic device according to a third embodiment of the present disclosure.

FIG. 5 schematically illustrates a cross-sectional view of an electronic device according to a fourth embodiment of the present disclosure.

FIG. 6 schematically illustrates a cross-sectional view of an electronic device according to a fifth embodiment of the present disclosure.

FIG. 7 schematically illustrates a cross-sectional view of an electronic device according to a variant embodiment of the fifth embodiment of the present disclosure.

FIG. 8 schematically illustrates a cross-sectional view of an electronic device according to a sixth embodiment of the present disclosure.

FIG. 9 schematically illustrates a cross-sectional view of an electronic device according to a seventh embodiment of the present disclosure.

FIG. 10 schematically illustrates a cross-sectional view of an electronic device according to an eighth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

In the present disclosure, the length, width, thickness, height or area of an element or the distance or spacing between elements may be measured through optical microscopy, scanning electron microscope, α-step, ellipsometer or other suitable methods. In detail, according to some embodiments, the scanning electron microscope can be used to obtain cross-sectional images of the elements to be measured, and the lengths, widths, thicknesses, heights or areas of the elements, or the distance or spacing between the elements may be measured, but not limited thereto.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode, a varactor diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. In the following, the display device is taken as an example of the electronic device to describe the contents of the present disclosure, but the present disclosure is not limited thereto. In some embodiments, the electronic device may include combinations of display device and other devices.

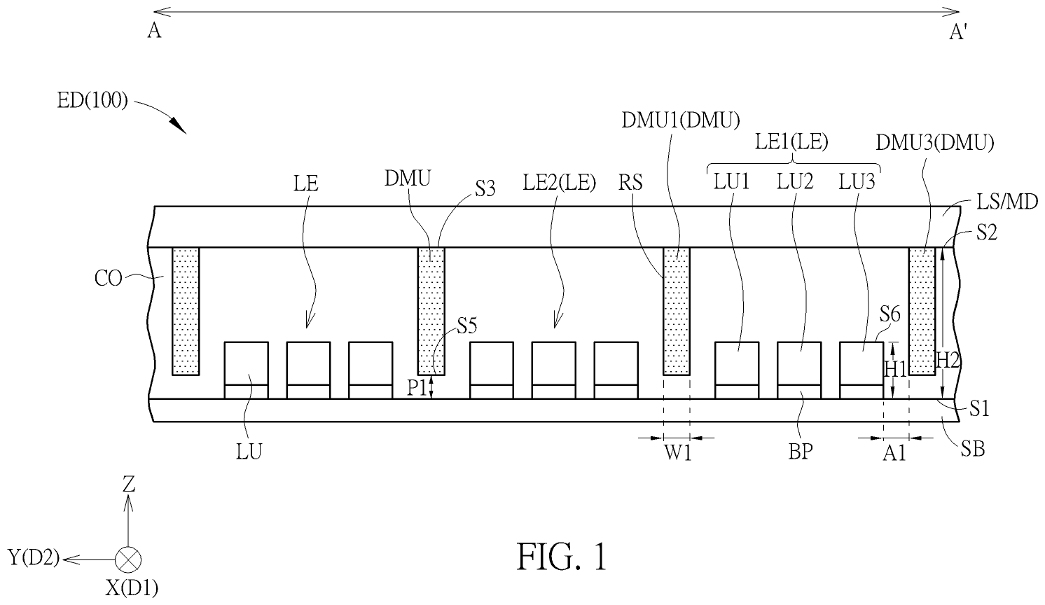

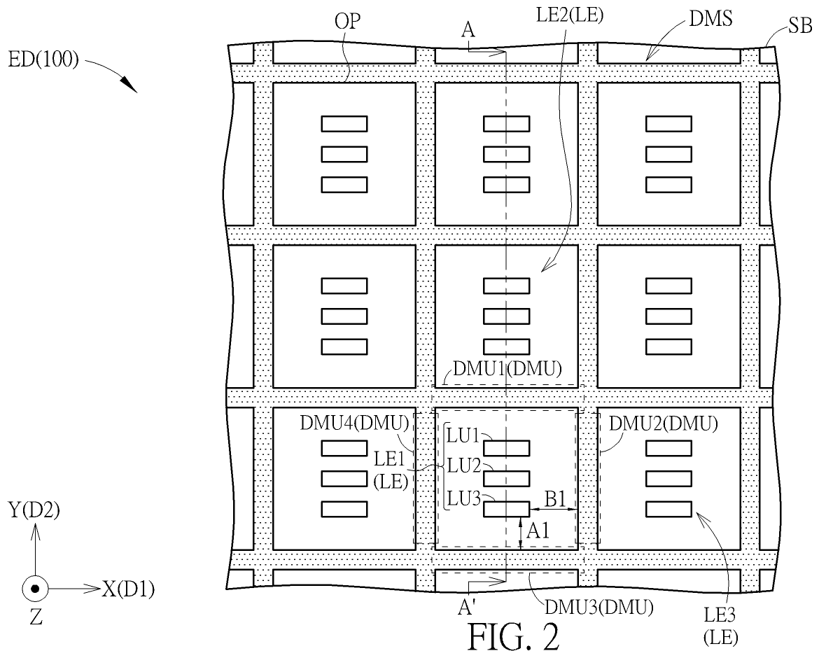

Referring to FIG. 1 and FIG. 2, FIG. 1 schematically illustrates a cross-sectional view of an electronic device according to a first embodiment of the present disclosure, and FIG. 2 schematically illustrates a top view of the electronic device according to the first embodiment of the present disclosure. Specifically, FIG. 1 shows the cross-sectional view of the structure shown in FIG. 2 along a section line A-A′. The electronic device ED of the present embodiment may include a display device 100, but not limited thereto. In some embodiments, the electronic device ED may include combinations of the display device 100 and other suitable electronic devices. According to the present embodiment, as shown in FIG. 1, the electronic device ED may include a substrate SB and a plurality of light emitting elements LE disposed on the substrate SB. Specifically, the light emitting elements LE are disposed on the top surface S1 of the substrate SB. The light emitting elements LE may be bonded to the substrate SB, such that the light emission of the light emitting elements LE may be controlled through the substrate SB. For example, the substrate SB may include a structure formed by stacking insulating layer(s) and conductive layer(s), and the light emitting elements LE may be electrically connected to the conductive layer(s) of the substrate SB. The substrate SB may include a flexible substrate or a non-flexible substrate. The substrate SB of the present embodiment may include a printed circuit board (PCB), a flexible printed circuit board (FPCB), glass, ceramic, quartz, sapphire, acrylic, polyimide (PI), polyethylene terephthalate (PET), polycarbonate (PC), other suitable materials or combinations of the above-mentioned materials, but not limited thereto. In other words, the electronic device ED may for example be formed through a chip on board (COB) process, but not limited thereto. It should be noted that the substrate SB is exemplarily shown as a single layer in FIG. 1, in which the detailed structure of the substrate SB is not shown.

In the present embodiment, the light emitting element LE may include at least one light emitting unit LU, or in other words, the light emitting element LE may be formed of at least one light emitting unit LU. In other words, “the light emitting element LE” of the present disclosure may be a group of light emitting units LU including one or more light emitting units LU. The number of the light emitting units LU in a light emitting element LE may be determined according to the design of the electronic device ED. For example, as shown in FIG. 1, one of the light emitting elements LE of the electronic device ED may include three light emitting units LU, that is, the light emitting unit LU1, the light emitting unit LU2 and the light emitting unit LU3, but not limited thereto. The light emitting unit LU1, the light emitting unit LU2 and the light emitting unit LU3 may be bonded to the substrate SB respectively through a bonding pad BP. The bonding pad BP may include any suitable conductive material, such as metal materials, but not limited thereto. In some embodiments, the light emitting unit LU1, the light emitting unit LU2 and the light emitting unit LU3 may emit lights of the same color, such as blue light. In some embodiments, the light emitting unit LU1, the light emitting unit LU2 and the light emitting unit LU3 may emit lights of different colors. For example, the light emitting unit LU1, the light emitting unit LU2 and the light emitting unit LU3 may respectively emit red light, green light, and blue light, which can be mixed into a white light, but not limited thereto. In such condition, the light emitting unit LU1, the light emitting unit LU2 and the light emitting unit LU3 may form a pixel, that is, a light emitting element LE may be regarded as a pixel. The light emitting unit LU may include a light emitting diode, such as inorganic light emitting diode. The inorganic light emitting diode may include mini light emitting diode (mini LED), micro light emitting diode (micro LED) or quantum dot light emitting diode (QLED), but not limited thereto.

As shown in FIG. 1, the electronic device ED may further include a cover layer CO disposed on the substrate SB. Specifically, the cover layer CO may be entirely disposed on the top surface S1 of the substrate SB and cover the top surface S1 of the substrate SB and the light emitting elements LE. The cover layer CO may be used to encapsulate the light emitting elements LE to provide protection or moisture/oxygen blocking effect to the light emitting elements LE. The cover layer CO may include any suitable light-transmitting material, such that the light emitted from the light emitting units LU may pass through the cover layer CO. In the present embodiment, the cover layer CO may include any suitable material with a refractive index between the refractive index of the light emitting element LE (or the light emitting unit LU) and the refractive index of the layer located on the cover layer CO (for example, the light shielding layer LS or the medium layer MD, which will be detailed in the following, but not limited thereto) to reduce the possibility of total reflection of the light emitting from the light emitting units LU at the top surface S2 of the cover layer CO, thereby improving the display effect of the electronic device ED. In some embodiments, the cover layer CO may include a material with a refractive index ranged from 1.0 to 2.4. In some embodiments, the cover layer CO may include a material with a refractive index ranged from 1.2 to 2.2. In some embodiments, the cover layer CO may include a material with a refractive index ranged from 1.4 to 2.0. For example, the cover layer CO may include optical glue with a refractive index of 1.5, but not limited thereto.

According to the present embodiment, the electronic device ED further includes at least one dam wall unit DMU disposed on the substrate SB, wherein in the cross-sectional view of the electronic device ED (for example, FIG. 1), the dam wall unit DMU may be disposed between adjacent two of the light emitting elements LE. “The adjacent two of the light emitting elements LE” described herein may indicate that no light emitting element LE or light emitting unit LU is included between the two light emitting elements LE. Therefore, in the normal direction of the electronic device ED (that is, the direction Z), the dam wall unit DMU may not overlap the light emitting element LE. In the present embodiment, the electronic device ED may include a plurality of dam wall units DMU respectively be disposed between any adjacent two of the light emitting elements LE, but not limited thereto. In other words, the dam wall unit DMU may be disposed between any adjacent two of the light emitting elements LE. For example, as shown in FIG. 2, the light emitting elements LE of the present embodiment may be arranged in an array and extend respectively along a first direction D1 (that is, the direction X) and a second direction D2 (that is, the direction Y), and the electronic device ED may include a plurality of dam wall units DMU respectively extending along the first direction D1 and the second direction D2, wherein the dam wall unit DMU extending along the first direction D1 may be disposed between two adjacent light emitting elements LE arranged along the second direction D2, and the dam wall unit DMU extending along the second direction D2 may be disposed between two adjacent light emitting elements LE arranged along the first direction D1. For example, the electronic device ED may include a dam wall unit DMU1 extending along the first direction D1 and a dam wall unit DMU2 extending along the second direction D2, wherein the dam wall unit DMU1 may be disposed between the light emitting element LE1 and the light emitting element LE2, and the dam wall unit DMU2 may be disposed between the light emitting element LE1 and the light emitting element LE3. In such condition, in the normal direction of the electronic device ED, a light emitting element LE may for example be surrounded by four dam wall units DMU, but not limited thereto. The dam wall units DMU shown in FIG. 1 may for example be the cross-sectional view of the dam wall units DMU extending along the first direction D1. In the present embodiment, the first direction D1 may be perpendicular to the second direction D2, but not limited thereto. In some embodiments, the first direction D1 and the second direction D2 may be any two directions which are not parallel to each other.

In the present embodiment, the plurality of dam wall units DMU may form a dam wall structure DMS disposed on the substrate SB. Specifically, as shown in FIG. 2, the plurality of dam wall units DMU respectively extending along the first direction D1 and the second direction D2 may be connected to each other and form the dam wall structure DMS, wherein the dam wall structure DMS may have a grid pattern or a matrix pattern and include a plurality of openings OP. In the present embodiment, one light emitting element LE may be disposed corresponding to one opening OP of the dam wall structure DMS. That is, the light emitting units LU disposed corresponding to an opening OP may be regarded as a light emitting element LE. The dam wall structure DMS may separate different light emitting elements LE, or in other words, the dam wall structure DMS may separate different groups of light emitting units LU. In short, the electronic device ED may include the dam wall structure DMS disposed on the substrate SB, and a portion of the dam wall structure DMS corresponding to a side of an opening OP may be defined as a dam wall unit DMU. It should be noted that the dam wall units DMU of the dam wall structure DMS may not be connected to each other in some embodiments.

The arrangement direction of the dam wall units DMU and the pattern of the dam wall structure DMS mentioned above are exemplary, and the present embodiment is not limited thereto. In some embodiments, the arrangement of the dam wall units DMU or the pattern of the dam wall structure DMS may be determined according to the disposition way of the light emitting elements LE, such that the dam wall units DMU may be disposed between any adjacent two of the light emitting elements LE.

In the present embodiment, the dam wall unit DMU may include the material with high reflectivity. For example, the dam wall unit DMU may include any suitable material with a reflectivity of greater than or equal to 60%, but not limited thereto. In some embodiments, the dam wall unit DMU may include any suitable material with a reflectivity of greater than or equal to 708. In some embodiments, the dam wall unit DMU may include any suitable material with a reflectivity of greater than or equal to 80%. For example, the dam wall unit DMU of the present embodiment may include silicone or epoxy resin in which high reflectivity material (for example, titanium dioxide (TiO), barium sulfate (BaSO₄), zirconium dioxide (ZrO), and the like) is added or metal materials with high reflectivity, such as silver (Ag), gold (Au), copper (Cu), but not limited thereto. Therefore, the dam wall unit DMU may reflect the light emitted from the light emitting units LU.

According to the present embodiment, as shown in FIG. 1, the cover layer CO may include at least one recess RS, and the dam wall unit DMU may be disposed in the recess RS of the cover layer CO. The disposition position of the recess RS may correspond to the disposition position of the dam wall unit DMU. That is, the recess RS may be located between two adjacent light emitting elements LE. Specifically, the manufacturing method of the electronic device ED of the present disclosure may include the following steps:
S100: providing a substrate SB;
S102: disposing light emitting elements LE on the substrate SB;
S104: disposing a cover layer CO on the substrate SB;
S106: forming a recess RS in the cover layer CO; and
S108: forming dam wall units DMU in the recess RS.

It should be noted that the manufacturing method of the electronic device ED of the present embodiment may further include disposition of other elements or layers, which is not limited to the method mentioned above.

In detail, the manufacturing method of the electronic device ED may include the step S100: providing the substrate SB, the step S102: disposing the light emitting elements LE on the substrate SB, and the step S104: disposing the cover layer CO on the substrate SB at first. The details of the above-mentioned steps may refer to the contents mentioned above, and will not be redundantly described.

After the cover layer CO is formed, the step S106 may be performed to form the recess RS in the cover layer CO. Specifically, a cutting process may be performed on the cover layer CO, such that a portion of the cover layer CO is removed to form the recess RS in the cover layer CO. The cutting process of the cover layer CO may for example be performed through wheel cutter or other suitable cutting tools. In the present embodiment, the cover layer CO may be cut according to the predetermined disposition position of the dam wall structure DMS to form the recess RS. The pattern of the recess RS may be the same as the pattern of the dam wall structure DMS disposed later. For example, the recess RS having a matrix pattern may be formed in the cover layer CO through the cutting process, wherein the plurality of light emitting elements LE may be separated from each other through the recess RS in the normal direction of the substrate SB (that is, the direction Z), but not limited thereto.

After the recess RS is formed, the step S108 may be performed to form the dam wall units DMU in the recess RS. Specifically, the material of the dam wall unit DMU may be filled into the recess RS to form the dam wall units DMU, thereby forming the dam wall structure DMS. For example, the material of the dam wall unit DMU (may refer to the contents mentioned above, which will not be redundantly described) may be disposed in the recess RS through inkjet printing or other suitable processes at first. After that, a polishing process may be performed to remove the portion of the material of the dam wall unit DMU overflow from the recess RS (if any), thereby forming the dam wall units DMU. The above-mentioned polishing process may further smoothen the top surface S3 of the dam wall units DMU and the top surface S2 of the cover layer CO. Therefore, the cover layer CO may further serve as a planarization layer to facilitate disposition of other elements or layers thereon. In the present embodiment, after the polishing process, the top surface S3 of the dam wall units DMU may be aligned with the top surface S2 of the cover layer CO, but not limited thereto. Through the processes mentioned above, the dam wall units DMU disposed in the recess RS may be formed.

According to the present embodiment, in the cross-sectional view of the electronic device ED, the dam wall unit DMU may have a width W1 in a direction parallel to the surface (for example, the top surface S1) of the substrate SB. Specifically, the width W1 may be the width of the dam wall unit DMU in the first direction D1 or the second direction D2. For example, FIG. 1 shows the dam wall units DMU extending along the first direction D1, wherein the dam wall units DMU may have the width W1 in the second direction D2. In addition, although it is not shown in the figure, the dam wall units DMU extending along the second direction D2 may have the width W1 in the first direction D1. In some embodiments, a dam wall unit DMU may extend along a direction, and the dam wall unit DMU may have the width W1 in another direction perpendicular to the direction. The widths W1 of different dam wall units DMU may be the same or different, the present disclosure is not limited thereto. In the present embodiment, the width W1 may range from 20 micrometers (μm) to 500 μm (that is, 20 μm≤W1≤500 μm). In some embodiments, the width W1 may range from 40 μm to 450 μm (that is, 40 μm≤W1≤450 μm). In some embodiments, the width W1 may from 60 μm to 400 μm (that is, 60 μm≤W1≤400 μm). Specifically, in the cutting process of the cover layer CO mentioned above, the width of the cutting tool (for example, wheel cutter) may be adjusted to be within the above-mentioned range, such that the width of the recess RS formed may be within the above-mentioned range. Therefore, after the dam wall units DMU are disposed in the recess RS, the width W1 of the dam wall units DMU may be within the above-mentioned range. In other words, in the cutting process of the cover layer CO, the wheel cutter with a width ranged from 20 μm to 500 μm may be selected to cut the cover layer CO, but not limited thereto. When the width W1 of the dam wall unit DMU is less than 20 μm, the reflection effect of the dam wall unit DMU may be poor; when the width W1 of the dam wall unit DMU is greater than 500 μm, the spatial configuration of the light emitting elements LE on the substrate SB may be affected.

According to the present embodiment, the dam wall units DMU are not in contact with the substrate SB, or in other words, the dam wall units DMU are not in contact with the top surface S1 of the substrate SB. In other words, the dam wall units DMU are not directly disposed on the substrate SB. Specifically, when the cutting process of the cover layer CO is performed to form the recess RS, the cover layer CO would not be cut through, such that the recess RS may not penetrate through the cover layer CO, or the recess RS may not expose the top surface S1 of the substrate SB. Therefore, the dam wall units DMU disposed in the recess RS may not contact the substrate SB. In such condition, as shown in FIG. 1, the dam wall unit DMU may include a bottom surface S5 adjacent to the top surface S1 of the substrate SB, wherein a spacing P1 is included between the bottom surface S5 of the dam wall unit DMU and the top surface S1 of the substrate SB, and the spacing P1 is greater than 0. In other words, the bottom surface S5 of the dam wall unit DMU does not contact the top surface S1 of the substrate SB. Therefore, a portion of the cover layer CO may be located between the dam wall unit DMU and the substrate SB, or in other words, a portion of the cover layer CO may be located between the bottom surface S5 of the dam wall unit DMU and the top surface S1 of the substrate SB. According to the present embodiment, the spacing P1 may range from 1 μm to 30 μm (that is, 1 μm≤P1≤30 μm), but not limited thereto. In some embodiments, the spacing P1 may range from 3 μm to 25 μm (that is, 3 μm≤P1≤25 μm). In some embodiments, the spacing P1 may range from 5 μm to 20 μm (that is, 5 μm≤P1≤20 μm). Through the above-mentioned design, the possibility of the substrate SB (such as the conductive layer in the substrate SB) being damaged by the cutting tool during the cutting process of the cover layer CO may be reduced, thereby improving the reliability of the electronic device ED.

According to the present embodiment, the electronic device ED may further include a light shielding layer LS disposed on the cover layer co, but not limited thereto. In detail, the light shielding layer LS may be directly disposed on the dam wall units DMU (or the dam wall structure DMS) and/or the cover layer CO. Specifically, after the above-mentioned polishing process, the light shielding layer LS may be disposed on the cover layer CO and/or the dam wall units DMU through any suitable process. In the normal direction of the electronic device ED, the light shielding layer LS may overlap the dam wall units DMU. In other words, the light shielding layer LS may cover the top surfaces S3 of the dam wall units DMU. For example, as shown in FIG. 1, the light shielding layer LS may be entirely disposed on the cover layer CO, but not limited thereto. In such condition, the light shielding layer LS may directly contact the top surface S2 of the cover layer CO and the top surfaces S3 of the dam wall units DMU, that is, the light shielding layer LS may cover the top surfaces S3 of the dam wall units DMU and the top surface S2 of the cover layer CO. In some embodiments, the light shielding layer LS may be disposed corresponding to the dam wall units DMU (or the dam wall structure DMS). In such condition, although it is not shown in the figure, the light shielding layer LS may be a patterned layer, and the pattern of the light shielding layer LS may for example be the same as the pattern of the dam wall structure DMS. In some embodiments, the light shielding layer LS may have any suitable pattern, such that the light shielding layer LS may at least be disposed on the dam wall units DMU and cover the top surfaces S3 of the dam wall units DMU. The light shielding layer LS may reduce the brightness of the light passing through the light shielding layer LS. In the present embodiment, the light shielding layer LS may include any suitable material with a transmittance ranged from 50% to 95%. For example, the material of the light shielding layer LS may include silicone or epoxy resin with black dye or carbon nanotubes added, but not limited thereto. By disposing the light shielding layer LS that at least covers the top surfaces S3 of the dam wall units DMU, the possibility of light (such as ambient light) from outside the electronic device ED being reflected by the dam wall units DMU and being observed by the user may be reduced, thereby reducing the influence of non-display light on the display effect of the electronic device ED.

As shown in FIG. 1, the electronic device ED of the present embodiment may include a medium layer MD directly disposed on the cover layer CO. Specifically, the layer directly disposed on the cover layer CO in the electronic device ED may be defined as the medium layer MD, and the medium layer MD may be any suitable layer according to the design of the electronic device ED. For example, in the structure shown in FIG. 1, the light shielding layer LS directly disposed on the cover layer CO may be the medium layer MD. In some embodiments, the electronic device ED may not include the light shielding layer LS but include another layer directly disposed on the cover layer CO, and the another layer may be the medium layer MD. In some embodiments, there is no layer disposed on the cover layer CO. In such condition, the medium layer MD may include air. The definition of the medium layer MD in the following may refer to the contents above, which will not be redundantly described.

In the present embodiment, in the top view direction of the electronic device ED (that is, parallel to the direction Z), a minimum distance A1 may be included between a light emitting element LE and a dam wall unit DMU extending along the first direction D1. Specifically, the minimum distance A1 may be defined as the distance between a light emitting element LE and the dam wall unit DMU adjacent to the light emitting element LE and extending along the first direction D1. For example, as shown in FIG. 1 and FIG. 2, the electronic device ED includes a dam wall unit DMU3 adjacent to the light emitting element LE1 and extending along the first direction D1, wherein the minimum distance A1 is included between the light emitting element LE1 and the dam wall unit DMU3. “The minimum distance A1” mentioned above may be defined as the minimum distance between the dam wall unit DMU3 and the light emitting unit LU of the light emitting element LE1 that is closest to the dam wall unit DMU3 (that is, the light emitting unit LU3). The light emitting element LE1 may have a height H1, the dam wall unit DMU3 may have a height H2, wherein the minimum distance A1, the height H1 and the height H2 may satisfy the following equation (1):

tan⁻¹(A1/(H2−H1))≥θc (1)

In equation (1) above, the height H1 of the light emitting element LE1 may be defined as the height of the light emitting unit LU of the light emitting element LE1 that is closest to the dam wall unit DMU3 (that is, the light emitting unit LU3), wherein the height of the light emitting unit LU may be defined as the vertical distance between the top surface of the light emitting unit and the top surface S1 of the substrate SB. For example, in the present embodiment, the height H1 may be defined as the vertical distance between the top surface S6 of the light emitting unit LU3 and the top surface S1 of the substrate SB, but not limited thereto. In some embodiments, when the top surface S6 of the light emitting unit LU3 includes an uneven surface, the height H1 may be the vertical distance between the highest point on the top surface S6 of the light emitting unit LU3 and the top surface S1 of the substrate SB. In other words, the height H1 of the light emitting element LE1 may be determined according to the height of the light emitting unit LU that defines the minimum distance A1 (that is, the light emitting unit LU3). The height H2 of the dam wall unit DMU3 may be defined as the vertical distance between the top surface S3 of the dam wall unit DMU3 and the top surface S1 of the substrate SB. In some embodiments, when the top surface S3 of the dam wall unit DMU3 includes an uneven surface, the height H2 may be the vertical distance between the highest point on the top surface S3 of the dam wall unit DMU3 and the top surface S1 of the substrate SB. In addition, the term θc shown in equation (1) is the critical angle, and the value thereof may be determined according to the refractive index of the cover layer CO and the refractive index of the medium layer MD. Specifically, when the incident angle of a light at the interface between the cover layer CO and the medium layer MD is greater than the critical angle θc, total reflection of the light may occur. In such condition, the cover layer co has a refractive index N1, the medium layer MD has a refractive index N2, and the critical angle θc may be expressed by the following equation (2):

$$θ c = s i {n}^{- 1} ( N 2 / N 1 ) \qquad ( 2 )$$

The range of the refractive index N1 of the cover layer CO may refer to the contents above, and will not be redundantly described. In some embodiments, as mentioned above, the medium layer MD may be the light shielding layer LS, and the refractive index N2 may be the refractive index of the material of the light shielding layer LS. In some embodiments, the medium layer MD may include a layer, and the refractive index N2 may be the refractive index of the material of the layer. In some embodiments, the medium layer MD may include air, that is, the refractive index N2 may be 1. For example, in an embodiment, the cover layer CO may include optical glue and the refractive index N1 thereof may be 1.5, the medium layer MD may include air and having the refractive index N2 of 1, and the critical angle θc may be about 41.8 degrees, but not limited thereto.

Therefore, after combining equation (1) and equation (2), the relation between the minimum distance A1, the height H1, the height H2, the refractive index N1 and the refractive index N2 may be obtained, which is shown in the following equation (3):

$${tan}^{- 1} ( A 1 / ( H 2 - H 1 ) ) \geq {sin}^{- 1} ( N 2 / N 1 ) \qquad ( 3 )$$

In short, in the present embodiment, the critical angle θc may be defined according to the refractive index N1 of the cover layer CO and the refractive index N2 of the medium layer MD at first, and then, the minimum distance A1 between a light emitting element LE and a dam wall unit DMU adjacent to the light emitting element LE and extending along the first direction D1 may be defined, the height of the light emitting unit LU of the light emitting element LE closest to the dam wall unit DMU may be defined as the height H1 of the light emitting element LE, and the height of the dam wall unit DMU may be defined as the height H2, wherein the minimum distance A1, the height H1 and the height H2 may satisfy equation (3) shown above. The definition ways of the height H1 of the light emitting element LE and the height H2 of the dam wall unit DMU may refer to the contents mentioned above. It should be noted that the height H2 mentioned above generally indicates the heights of the dam wall units DMU extending along the first direction D1, and the heights H2 of these dam wall units DMU may be the same or different.

As shown in FIG. 2, the electronic device ED further includes another dam wall unit DMU1 adjacent to the light emitting element LE1 and extending along the first direction D1. In an embodiment, the minimum distance A1 may be the minimum distance between the light emitting element LE1 and the dam wall unit DMU1. In such condition, the height H1 of the light emitting element LE1 may be the height of the light emitting unit of the light emitting element LE1 closest to the dam wall unit DMU1 (that is, the light emitting unit LU1), and the dam wall unit DMU1 may have the height H2, wherein the minimum distance A1, the height H1 and the height H2 may satisfy the above-mentioned equation (3).

In addition, in the present embodiment, in the top view direction of the electronic device ED, a minimum distance B1 may be included between a light emitting element LE and a dam wall unit DMU extending along the second direction D2. Specifically, the minimum distance B1 may be defined as the minimum distance between a light emitting element LE and a dam wall unit DMU adjacent to the light emitting element LE and extending along the second direction D2. For example, as shown in FIG. 2, the electronic device ED includes a dam wall unit DMU2 adjacent to the light emitting element LE1 and extending along the second direction D2, wherein a minimum distance B1 may be included between the light emitting element LE1 and the dam wall unit DMU2. “The minimum distance B1” mentioned above may be defined as the minimum distance between the dam wall unit DMU2 and the light emitting unit LU of the light emitting element LE1 that is closest to the dam wall unit DMU2. For example, the minimum distance B1 shown in FIG. 2 may be the distance between the light emitting unit LU3 and the dam wall unit DMU2, but not limited thereto. In some embodiments, the light emitting unit LU of the light emitting element LE1 closest to the dam wall unit DMU2 may be the light emitting unit LU1 (or the light emitting unit LU2), and the minimum distance B1 may be the distance between the light emitting unit LU1 (or the light emitting unit LU2) and the dam wall unit DMU2. Similarly, the height H1 of the light emitting element LE1 may be defined as the height of the light emitting unit LU of the light emitting element LE1 closest to the dam wall unit DMU2, and the definition of the height of the light emitting unit LU may refer to the contents mentioned above. The dam wall unit DMU2 may have a height H3 (not shown), wherein the definition of the height H3 may refer to the definition of the height H2 mentioned above. In the present embodiment, the minimum distance B1, the height H1, and the height H3 may satisfy the following equation (4):

$${tan}^{- 1} ( B 1 / ( H 3 - H 1 ) ) \geq {sin}^{- 1} ( N 2 / N 1 ) \qquad ( 4 )$$

The derivation of equation (4) and the features of the refractive index N1 and the refractive index N2 shown in equation (4) may refer to the contents mentioned above. The height H3 mentioned above generally indicates the heights of the dam wall units DMU extending along the second direction D2, and the heights H3 of these dam wall units DMU may be the same or different. In short, in the present embodiment, the minimum distance B1 between a light emitting element LE and a dam wall unit DMU adjacent to the light emitting element LE and extending along the second direction D2 may be defined, the height of the light emitting unit LU of the light emitting element LE closest to the dam wall unit DMU may be defined as the height H1 of the light emitting element LE, and the height of the dam wall unit DMU may be defined as the height H3, wherein the minimum distance B1, the height H1 and the height H3 may satisfy equation (4) shown above.

As shown in FIG. 2, the electronic device ED further includes a dam wall unit DMU4 adjacent to the light emitting element LE1 and extending along the second direction D2. In an embodiment, the minimum distance B1 may be the minimum distance between the light emitting element LE1 and the dam wall unit DMU4. In such condition, the height H1 of the light emitting element LE1 may be defined as the height of the light emitting unit of the light emitting element LE1 closest to the dam wall unit DMU4, and the dam wall unit DMU4 may have the height H3, wherein the minimum distance B1, the height H1 and the height H3 may satisfy equation (4) shown above.

According to the present embodiment, by making the electronic device ED include the dam wall units DMU disposed between the light emitting elements LE, and making the size designs of the light emitting elements LE and the dam wall units DMU satisfy the above-mentioned equation (3) and/or equation (4), the light emitted from the light emitting elements LE may be reflected by the dam wall units DMU, such that the possibility of total reflection of light may be reduced, thereby improving the display effect of the electronic device ED. For example, through the above-mentioned designs, the light with an incident angle greater than the critical angle θc at the interface between the cover layer CO and the medium layer MD may be reflected by the dam wall units DMU to reduce total reflection of the light, thereby increasing the amount of output light of the electronic device ED. In a comparative embodiment, when the size designs of the light emitting elements LE and the dam wall units DMU do not satisfy the above-mentioned equation (3) and/or equation (4), the dam wall units DMU may block the normal display light, thereby causing display abnormalities such as color variation. It should be noted that the above-mentioned features may be applied to other light emitting elements LE and the dam wall units DMU surrounding those light emitting elements LE of the electronic device ED, which is not limited to the light emitting element LE1 and the dam wall units DMU surrounding the light emitting element LE1.

It should be noted that the structure of the electronic device ED of the present embodiment is not limited to what is shown in the figure and may include other suitable elements or layers. Other embodiments of the present disclosure will be described in the following. In order to simplify the description, the same elements or layers in the following embodiments would be labeled with the same symbol, and the features thereof will not be redundantly described. The differences between the embodiments will be detailed in the following.

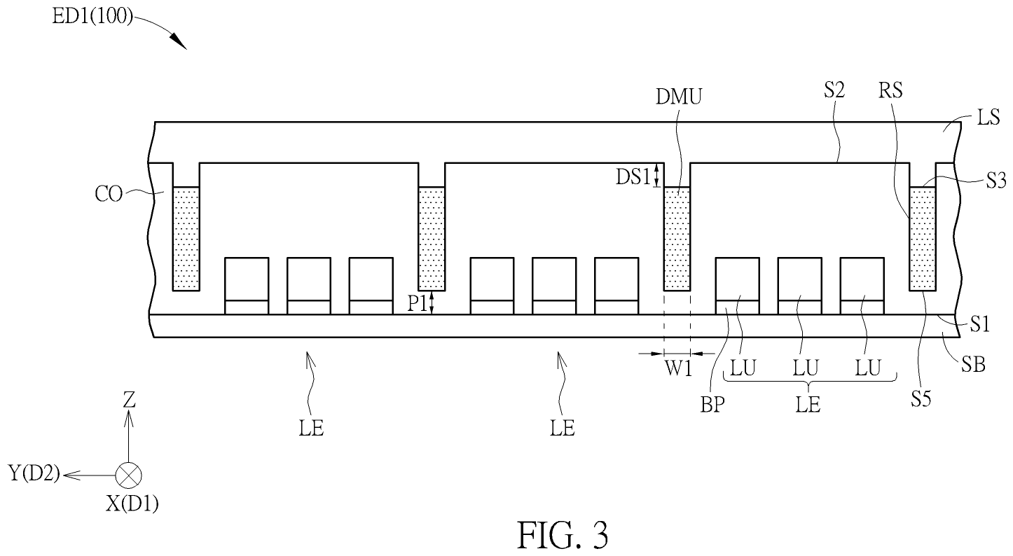

Referring to FIG. 3, FIG. 3 schematically illustrates a cross-sectional view of an electronic device according to a second embodiment of the present disclosure. According to the present embodiment, the dam wall unit DMU may include the top surface S3 opposite to the bottom surface S5 of the dam wall unit DMU, and the cover layer CO may include a top surface S2 opposite to the top surface S1 of the substrate SB, wherein in the cross-sectional view of the electronic device ED1 (for example, FIG. 3), the top surface S3 of the dam wall unit DMU may be lower than the top surface S2 of the cover layer CO. In other words, the top surface S3 of the dam wall unit DMU may not be aligned with the top surface S2 of the cover layer CO. Specifically, in the manufacturing method of the electronic device ED1 of the present embodiment, after the cutting process is performed on the cover layer CO, the material of the dam wall unit DMU may be disposed in the recess RS through inkjet printing or other suitable processes, wherein the material of the dam wall unit DMU may not fully fill the recess RS, such that the top surface S3 of the dam wall unit DMU is lower than the top surface S2 of the cover layer CO. In such condition, the manufacturing method of the electronic device ED1 may not include the polishing process mentioned above, but not limited thereto, According to the present embodiment, a vertical distance DS1 may be included between the top surface S3 of the dam wall unit DMU and the top surface S2 of the cover layer CO, wherein the vertical distance DS1 may range from 5 μm to 200 μm (that is, 5 μm≤DS1≤200 μm), but not limited thereto. In some embodiments, the vertical distance DS1 may range from 10 μm to 180 μm (that is, 10 μm≤DS1≤180 μm). In some embodiments, the vertical distance DS1 may range from 15 μm to 160 μm (that is, 15 μm≤DS1≤160 μm). After the dam wall units DMU are disposed, the material of the light shielding layer LS may be disposed on the cover layer CO through any suitable process, wherein the material of the light shielding layer LS may be filled into the recess RS. Therefore, as shown in FIG. 3, a portion of the light shielding layer LS may be filled into the recess RS and contacts the top surface S3 of the dam wall unit DMU in the present embodiment, that is, the light shielding layer LS may partially be disposed in the recess RS. In such condition, the thickness of the portion of the light shielding layer LS corresponding to the dam wall units DMU may be greater than the thickness of the portion of the light shielding layer LS corresponding to the cover layer CO. Through the above-mentioned design, the possibility of the light (such as ambient light) from outside the electronic device ED1 being reflected by the dam wall units DMU and being observed by the user may be reduced. It should be noted that although the light shielding layer LS is entirely disposed on the cover layer CO in FIG. 3, the present embodiment is not limited thereto.

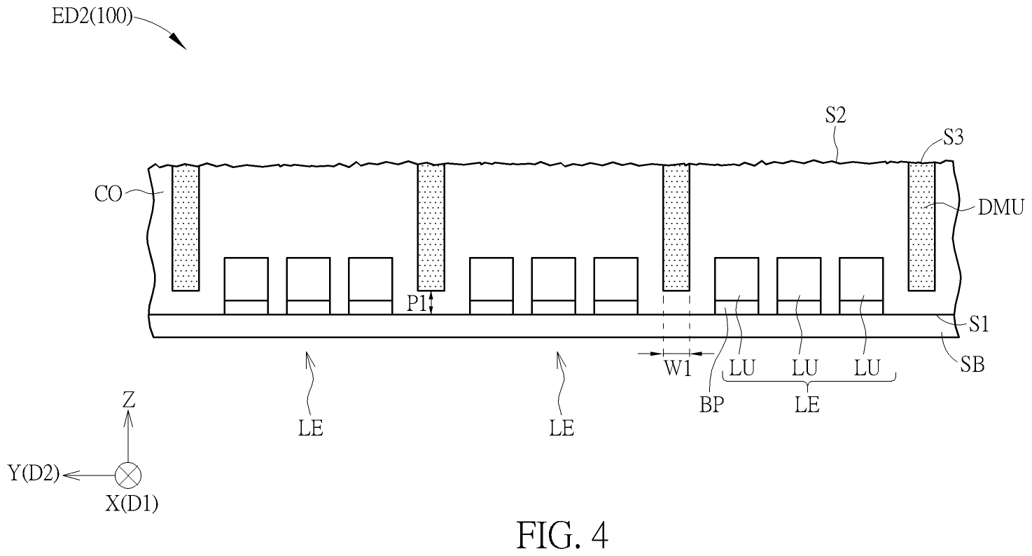

Referring to FIG. 4, FIG. 4 schematically illustrates a cross-sectional view of an electronic device according to a third embodiment of the present disclosure. According to the present embodiment, the top surface S2 of the cover layer CO and the top surface S3 of the dam wall unit DMU of the electronic device ED2 may include rough surfaces. Specifically, in the manufacturing method of the electronic device ED2, after the dam wall units DMU are disposed in the recess RS, and the polishing process is performed on the cover layer CO and the dam wall units DMU, a surface treatment may be performed on the top surface S2 of the cover layer CO and the top surfaces S3 of the dam wall units DMU, such that the top surface S2 of the cover layer CO and the top surfaces S3 of the dam wall units DMU become rough surfaces. By making the top surface S2 of the cover layer CO and/or the top surfaces S3 of the dam wall units DMU include rough surfaces, the possibility of the light (such as ambient light) from outside the electronic device ED2 being reflected by the dam wall units DMU and being observed by the user may be reduced. In the present embodiment, the electronic device ED2 may not include the light shielding layer LS mentioned above, but not limited thereto.

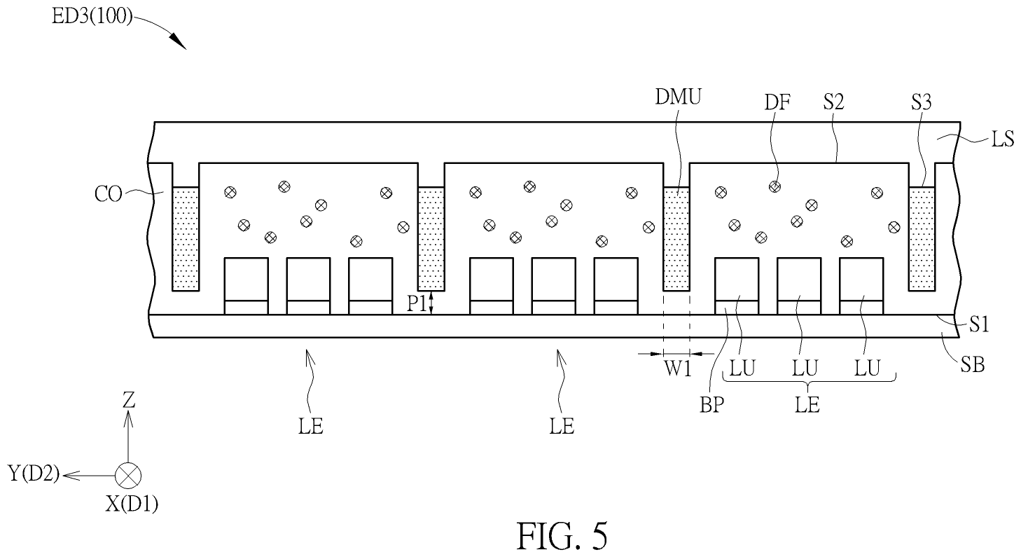

Referring to FIG. 5, FIG. 5 schematically illustrates a cross-sectional view of an electronic device according to a fourth embodiment of the present disclosure. According to the present embodiment, the electronic device ED3 may further include a plurality of diffusing particles DF disposed in the cover layer CO. Specifically, the diffusing particles DF may be distributed in the portion of the cover layer CO corresponding to the light emitting elements LE. The diffusing particles DF may be located at a side of the light emitting element LE opposite to the substrate SB, such that the light emitted from the light emitting element LE may pass through the diffusing particles DF. By disposing diffusing particles DF in the cover layer CO at the position corresponding to the light emitting elements LE, the light emitting effect of the electronic device ED3 may be improved. It should be noted that the structure of the light shielding layer LS of the present embodiment is not limited to what is shown in FIG. 5, and the structure thereof may refer to the structures of the light shielding layers LS in the above-mentioned embodiments. In some embodiments, the electronic device ED3 may not include the light shielding layer LS.

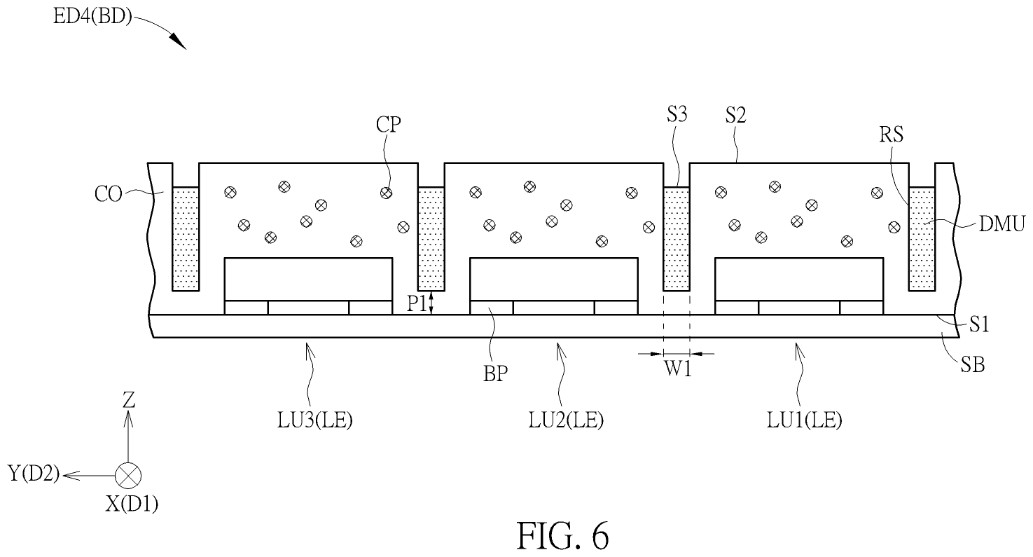

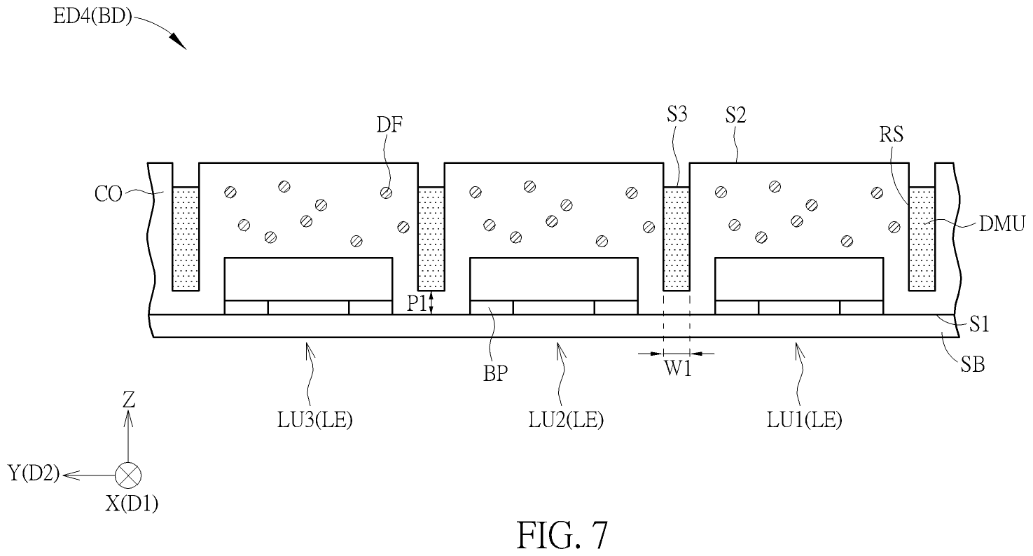

Referring to FIG. 6 and FIG. 7, FIG. 6 schematically illustrates a cross-sectional view of an electronic device according to a fifth embodiment of the present disclosure, and FIG. 7 schematically illustrates a cross-sectional view of an electronic device according to a variant embodiment of the fifth embodiment of the present disclosure. According to the present embodiment, one light emitting element LE of the electronic device ED4 may include one light emitting unit LU. For example, FIG. 6 and FIG. 7 show the structures in which three light emitting elements LE respectively include the light emitting unit LU1, the light emitting unit LU2 and the light emitting unit LU3. In other words, in the cross-sectional view of the electronic device ED4, the dam wall units DMU may be disposed between adjacent two of the light emitting units LU. In such condition, the minimum distance A1 (or the minimum distance B1) mentioned above may be defined as the minimum distance between a light emitting unit LU included in a light emitting element LE and the dam wall unit DMU adjacent to the light emitting element LE and extending along the first direction D1 (or the second direction D2), and the height H1 of the light emitting element LE may be the height of the light emitting unit LU. The electronic device ED4 of the present embodiment may for example include a back-light device BD, but not limited thereto. In some embodiments, the electronic device ED4 may include combinations of the back-light device BD and other electronic devices. In such condition, since a greater spacing may be include between the light emitting units LU in the back-light device BD, the width W1 of the dam wall unit DMU may range from 20 μm to 5 millimeters (mm) (that is, 20 μm≤W1≤5 mm), but not limited thereto. In addition, since the back-light device BD would not be easily affected by external light, the electronic device ED4 of the present embodiment may not include the above-mentioned light shielding layer LS, but not limited thereto. It should be noted that although FIG. 6 and FIG. 7 show the structure that the top surfaces S3 of the dam wall units DMU is lower than the top surface S2 of the cover layer CO, the present embodiment is not limited thereto.

According to the present embodiment, as shown in FIG. 6, the electronic device ED4 may further include a plurality of color converting particles CP disposed in the cover layer CO. Specifically, the color converting particles CP may be distributed in the portion of the cover layer CO corresponding to the light emitting elements LE (or the light emitting units LU). The color converting particles CP may include any suitable material that can change the wavelength or color of the light passing through the color converting particles CP. In other words, the color or wavelength of the light emitted from the light emitting units LU may be converted through the color converting particles CP. The color converting particle CP may for example include color filter, quantum dot, fluorescent, phosphorescent, other suitable materials or combinations of the above-mentioned materials. The electronic device ED4 of the present embodiment may for example include the following implementation ways. In some embodiments, the light emitting unit LU of the light emitting element LE may emit blue light, and the color converting particles CP may partially convert the blue light into a yellow light, wherein the blue light and the yellow light may be mixed into a white light. In some embodiments, the light emitting unit LU of the light emitting element LE may emit blue light, and the color converting particles CP may partially convert the blue light into a green light and a red light, wherein the blue light, the green light and the red light may be mixed into a white light. In some embodiments, the color converting particles CP corresponding to different light emitting units LU may convert the light emitted from the light emitting units LU into different colors. For example, taken the structure in FIG. 6 as an example, the light emitting unit LU1, the light emitting unit LU2 and the light emitting unit LU3 may emit blue lights, the color converting particles CP corresponding to the light emitting unit LU1 may convert the light emitted from the light emitting unit LU1 into a red light, and the color converting particles CP corresponding to the light emitting unit LU2 may convert the light emitted from the light emitting unit LU2 into a green light. Therefore, the lights emitted from the light emitting unit LU1, the light emitting unit LU2 and the light emitting unit LU3 may respectively be a red light, a green light and a blue light, which can be mixed into a white light. In such condition, the color converting particle CP may not be disposed corresponding to the light emitting unit LU3, or the diffusing particles DF may be disposed corresponding to the light emitting unit LU3. It should be noted that the implementation ways of the electronic device ED4 mentioned above are exemplary, and the present disclosure is not limited thereto.

In a variant embodiment, as shown in FIG. 7, the electronic device ED4 may include the diffusing particles DF disposed in the cover layer CO, but not the color converting particle CP, but not limited thereto. In some embodiments, the cover layer CO of the electronic device ED4 may include the color converting particles CP and the diffusing particles DF at the same time.

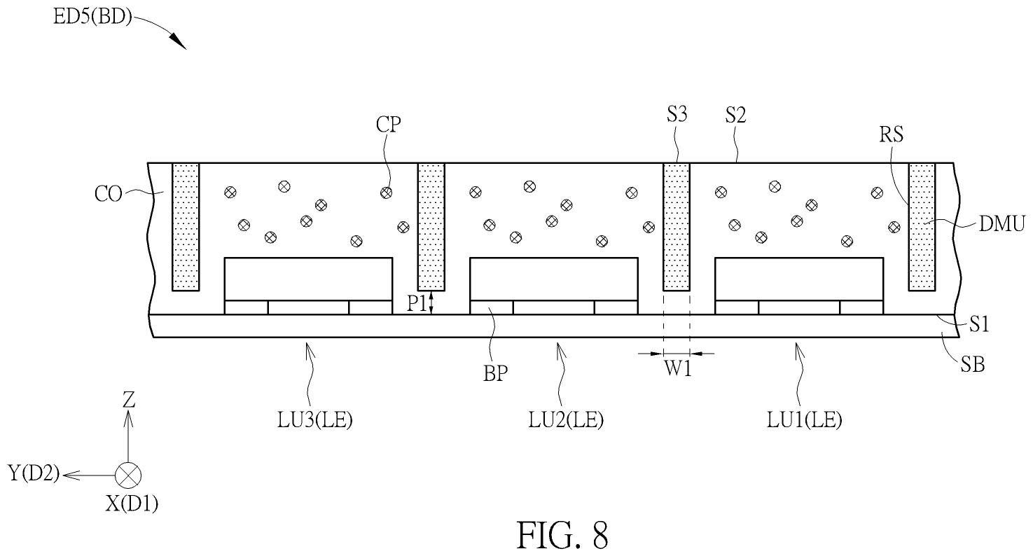

Referring to FIG. 8, FIG. 8 schematically illustrates a cross-sectional view of an electronic device according to a sixth embodiment of the present disclosure. One of the main differences between the electronic device ED5 of the present embodiment and the electronic device ED4 shown in FIG. 6 is the design of the dam wall unit DMU. According to the present embodiment, as shown in FIG. 8, the top surfaces S3 of the dam wall units DMU of the electronic device ED5 may be aligned with the top surface S2 of the cover layer CO. Specifically, the vertical distance between the top surface S3 of the dam wall unit DMU and the top surface S1 of the substrate SB may be the same as the vertical distance between the top surface S2 of the cover layer CO and the top surface S1 of the substrate SB. The above-mentioned structure may for example be formed by performing the polishing process on the cover layer CO and/or the dam wall units DMU, but not limited thereto. Through the above-mentioned design, the cross talk between two adjacent light emitting units LU may be reduced. The electronic device ED5 may further include the color converting particles CP disposed in the cover layer CO, but not limited thereto. In some embodiments, the electronic device ED5 may include the diffusing particles DF disposed in the cover layer CO. In some embodiments, the cover layer CO of the electronic device ED5 may include the color converting particles CP and the diffusing particles DF at the same time.

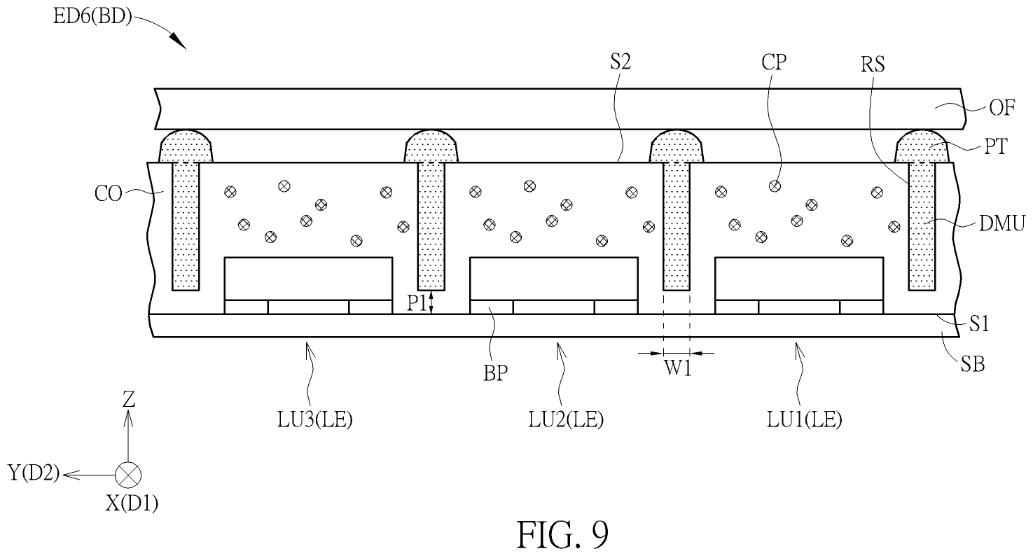

Referring to FIG. 9, FIG. 9 schematically illustrates a cross-sectional view of an electronic device according to a seventh embodiment of the present disclosure. One of the main differences between the electronic device ED6 of the present embodiment and the electronic device ED4 shown in FIG. 6 is the design of the dam wall unit DMU. According to the present embodiment, the dam wall units DMU of the electronic device ED6 may protrude from the cover layer CO. Specifically, as shown in FIG. 9, the dam wall unit DMU may for example include a portion PT, wherein the portion PT of the dam wall unit DMU may protrude from the top surface S2 of the cover layer CO. The portion PT of the dam wall unit DMU may be disposed on the cover layer CO. In such condition, the vertical distance between the highest point of the dam wall unit DMU and the top surface S1 of the substrate SB may be greater than the vertical distance between the top surface S2 of the cover layer CO and the top surface S1 of the substrate SB. By making the dam wall units DMU protrude from the cover layer CO, the cross talk between two adjacent light emitting units LU may be reduced. The structure of the dam wall unit DMU of the present embodiment may be applied to the embodiments and variant embodiments of the present disclosure.

In addition, the electronic device ED6 of the present embodiment may further include an optical film OF, wherein the optical film OF is disposed on the cover layer CO, but not limited thereto. Specifically, the optical film OF may be disposed on the dam wall units DMU, and the dam wall units DMU may support the optical film OF. The optical film OF may include any suitable element or layer that can improve the light emitting effect of the electronic device ED6. Since the dam wall units DMU may protrude from the cover layer Co in the present embodiment, the optical film OF and the cover layer CO may be separated from each other through the dam wall units DMU. Specifically, the portion PT of the dam wall unit DMU may be located between the optical film OF and the cover layer CO and serve as the spacer between the optical film OF and the cover layer CO. Therefore, the possibility of contact between optical film OF and cover layer CO may be reduced, thereby improving the light emitting effect of the electronic device ED6.

The electronic device ED6 may further include the color converting particles CP disposed in the cover layer CO, but not limited thereto. In some embodiments, the electronic device ED6 may include the diffusing particles DF disposed in the cover layer CO. In some embodiments, the cover layer CO of the electronic device ED6 may include the color converting particles CP and the diffusing particles DF at the same time.

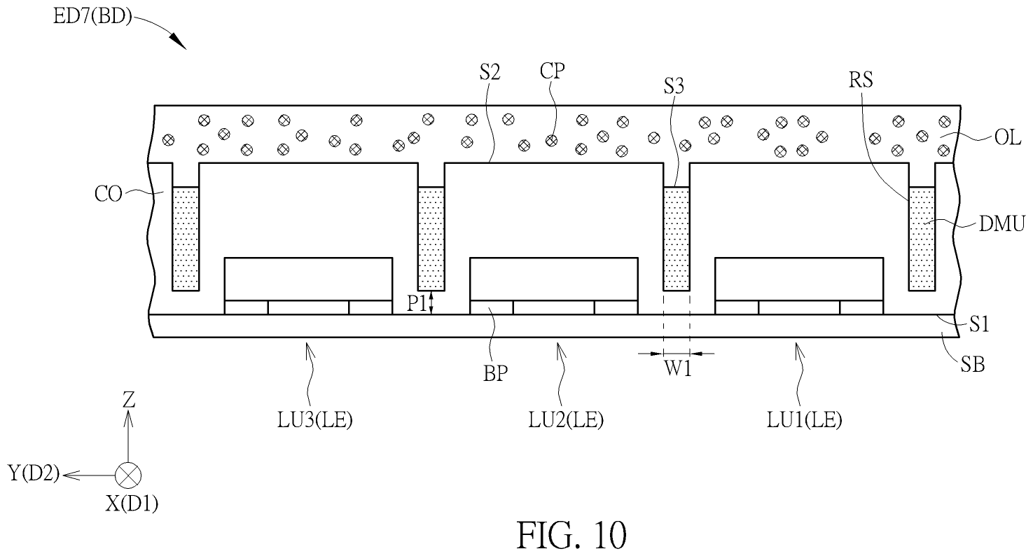

Referring to FIG. 10, FIG. 10 schematically illustrates a cross-sectional view of an electronic device according to an eighth embodiment of the present disclosure. According to the present embodiment, the electronic device ED7 may include an optical layer OL, wherein the optical layer OL may be disposed on the cover layer CO. In the present embodiment, the top surfaces S3 of the dam wall units DMU may be lower than the top surface S2 of the cover layer CO, and a portion of the optical layer OL may be disposed in the recess RS and contact the top surfaces S3 of the dam wall units DMU, but not limited thereto. In some embodiments, the top surfaces S3 of the dam wall units DMU may be aligned with the top surface S2 of the cover layer CO (as shown in FIG. 8), or the dam wall units DMU may protrude from the cover layer CO (as shown in FIG. 9). The color converting particles CP are disposed in the optical layer OL. For example, the optical layer OL may include a filling material and the color converting particles CP distributed in the filling material, but not limited thereto. In other words, in the present embodiment, the color converting particles CP may be disposed in the optical layer OL but not in the cover layer CO. Compared with the electronic devices in the above-mentioned embodiments, the color converting particles CP in the electronic device ED7 of the present embodiment may be disposed in the layer with a smaller height change (that is, the optical layer OL). Therefore, stability of color converting effect may be improved, thereby improving the light emitting effect of the electronic device ED7. In some embodiments, the optical layer OL may include the diffusing particles DF instead of the color converting particles CP. In some embodiments, the optical layer OL may include the diffusing particles DF and the color converting particles CP at the same time.

In summary, an electronic device is provided by the present disclosure. The electronic device includes a substrate, light emitting elements disposed on the substrate, a cover layer disposed on the substrate and covering the light emitting elements and a dam wall unit disposed between adjacent two of the light emitting elements. A spacing is included between the dam wall unit and the substrate, or in other words, a portion of the cover layer may be located between the dam wall unit and the substrate. Therefore, the possibility of the substrate being damaged during the manufacturing process of the electronic device may be reduced, thereby improving the reliability of the electronic device. In addition, through the size designs of the light emitting elements and the dam wall unit mentioned above, the possibility of total reflection of the light emitted from the light emitting elements may be reduced by the dam wall unit, thereby increasing the amount of output light of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a plurality of light emitting elements disposed on the substrate;
a cover layer disposed on the substrate and covering the plurality of light emitting elements; and
a dam wall unit disposed between adjacent two of the plurality of light emitting elements,
wherein the dam wall unit includes a bottom surface adjacent to a top surface of the substrate, and a spacing is included between the bottom surface of the dam wall unit and the top surface of the substrate.

2. The electronic device of claim 1, wherein the spacing ranges from 1 micrometer to 30 micrometers.

3. The electronic device of claim 1, wherein the spacing ranges from 3 micrometers to 25 micrometers.

4. The electronic device of claim 1, wherein the spacing ranges from 5 micrometers to 20 micrometers.

5. The electronic device of claim 1, wherein the cover layer includes a recess, and the dam wall unit is disposed in the recess.

6. The electronic device of claim 1, wherein the dam wall unit includes a top surface opposite to the bottom surface of the dam wall unit, the cover layer includes a top surface opposite to the substrate, and in a cross-sectional view of the electronic device, the top surface of the dam wall unit is lower than the top surface of the cover layer.

7. The electronic device of claim 6, wherein a distance is included between the top surface of the dam wall unit and the top surface of the cover layer, and the distance ranges from 5 micrometers to 200 micrometers.

8. The electronic device of claim 1, further comprising a light shielding layer disposed on the cover layer.

9. The electronic device of claim 8, wherein the cover layer includes a recess, the dam wall unit is disposed in the recess, and a portion of the light shielding layer is filled into the recess and contacts the dam wall unit.

10. The electronic device of claim 1, wherein a material of the dam wall unit has a reflectivity of greater than or equal to 60%.

11. The electronic device of claim 1, wherein the dam wall unit has a width in a cross-sectional view of the electronic device, and the width ranges from 20 micrometers to 500 micrometers.

12. The electronic device of claim 1, wherein the cover layer includes a top surface opposite to the substrate, and the top surface of the cover layer is a rough surface.

13. The electronic device of claim 1, wherein the dam wall unit includes a portion disposed on the cover layer.

14. The electronic device of claim 13, further comprising an optical film disposed on the cover layer, wherein the portion of the dam wall unit is disposed between the optical film and the cover layer.

15. An electronic device, comprising:
a substrate;
a light emitting element disposed on the substrate, wherein the light emitting element has a height H1;
a cover layer disposed on the substrate and covering the light emitting element;
a dam wall unit disposed on the substrate and extending along a first direction, wherein the dam wall unit has a height H2;
another dam wall unit disposed on the substrate and extending along a second direction different from the first direction, wherein the another dam wall unit has a height H3; and
a medium layer located on the cover layer,
wherein in a top view direction of the electronic device, a minimum distance A1 is included between the dam wall unit and the light emitting element, a minimum distance B1 is included between the another dam wall unit and the light emitting element, the cover layer has a refractive index N1, the medium layer has a refractive index N2, and the minimum distance A1 and the minimum distance B1 satisfy following equations:
$${tan}^{- 1} ( A 1 / ( H 2 - H 1 ) ) \geq {sin}^{- 1} ( N 2 / N 1 ) ; and$$
$${tan}^{- 1} ( B 1 / ( H 3 - H 1 ) ) \geq {sin}^{- 1} ( N 2 / N 1 ) .$$

16. The electronic device of claim 15, further comprising a plurality of diffusing particles or a plurality of color converting particles disposed in the cover layer.

17. The electronic device of claim 15, further comprising a light shielding layer disposed on the cover layer.

18. The electronic device of claim 17, wherein a transmittance of the light shielding layer ranges from 50% to 95%.

19. The electronic device of claim 15, wherein the medium layer is a light shielding layer.

20. The electronic device of claim 15, wherein the medium layer includes air.
